(19) United States
(12) Patent Application Publication
(10) Pub. No.: US 2026/0033034 A1
(43) Pub. Date: Jan. 29, 2026

(54) METHOD FOR REUSE OF GaAs SUBSTRATE EMPLOYED FOR EPITAXIAL CIGS SOLAR CELL

(71) Applicant: Korea Institute of Energy Technology, Naju-si (KR)

(72) Inventors: Jae Ho YUN, Seoul (KR); Jae Chang YANG, Changwon-si (KR)

(21) Appl. No.: 19/277,408

(22) Filed: Jul. 23, 2025

(30) Foreign Application Priority Data
Jul. 23, 2024 (KR) 10-2024-0097263

(51) Int. Cl. H10F 71/00; H10F 77/12; H10F 77/20

(52) U.S. Cl. CPC H10F 71/139; H10F 71/133; H10F 77/126; H10F 77/219

(57) ABSTRACT

An exemplary embodiment of the present disclosure is directed to providing a method of recycling GaAs substrates in epitaxial single crystalline CIGS (copper indium gallium selenide) solar cells. The method allows expensive single crystalline GaAs substrates to be recycled in implementing epitaxial single crystalline CIGS solar cells, and thus it is possible to reduce processing costs when commercializing solar cells.

### CROSS-REFERENCE TO RELATED APPLICATION

This application claims priority to Korean Patent Application No. 10-2024-0097263, filed on Jul. 23, 2024, and all the benefits accruing therefrom under 35 U.S.C. § 119, the contents of which in its entirety are herein incorporated by reference.

### BACKGROUND

### 1. Field

The present disclosure relates to a method of recycling GaAs substrates for manufacturing epitaxial single crystalline CIGS (copper indium gallium selenide) solar cells.

### 2. Description of the Related Art

Research of clean energy has been actively conducted due to problems such as resource depletion, resource price increase and environmental pollution. There are several research examples, but among them, research of solar cells has been continuously conducted to efficiently use solar energy.

A solar cell is a device that converts light energy of the sun into electrical energy. When sunlight is irradiated to a solar cell, electrons and holes are generated inside the solar cell. The generated electrons and holes move to the P- and N-poles contained in the solar cell, and a potential difference is generated between the P- and N-poles, and current flows.

The photoconversion efficiency of a solar cell that converts the solar light energy into electricity depends on the intensity and wavelength of light and the thickness and surface texture state of the solar cell, and the importance of a wafer increases as the thickness of the wafer becomes thinner by virtue of the development of silicon wafer cutting technology.

Recently, an epitaxial single crystalline CIGS solar cell has been implemented by using a GaAs substrate. By implementing an epitaxial single crystalline structure, a higher open voltage (Voc) and fill factor are possible as compared to a polycrystalline CIGS solar cell, resulting in improvement of energy conversion efficiency.

However, the GaAs substrate has a disadvantage in that it is expensive and requires high processing costs for commercialization. In order to solve the above-mentioned problem, a technology of recycling used GaAs substrates is required.

### REFERENCES

### Patent Documents

(Patent Document 1) KR 10-1213147 B1

### SUMMARY

The present disclosure is directed to providing a method of recycling GaAs substrates in epitaxial single crystalline CIGS (copper indium gallium selenide) solar cells.

The technical problems of the present disclosure are not limited to the above-mentioned technical problem, and the technical problems not mentioned may be clearly understood by those skilled in the art from the present specification and attached drawings.

In one aspect, there is provided a method of recycling GaAs substrates, including the steps of: forming an epitaxial CIGS (copper indium gallium selenide) light-absorbing layer on the top of a GaAs wafer; attaching a heat resistant structure to the edge of the top surface of the light-absorbing layer; forming an electrode layer on the top of the light-absorbing layer; attaching a carrier wafer to the top of the electrode layer; and separating the GaAs wafer through an epitaxial lift off process.

According to an exemplary embodiment of the present disclosure, the step of forming an epitaxial CIGS light-absorbing layer may include the steps of: depositing a sacrificial layer on the top of the GaAs wafer; forming an epitaxial GaAs thin film on the top of the sacrificial layer; and forming an epitaxial CIGS light-absorbing layer on the top of the GaAs thin film.

According to an exemplary embodiment of the present disclosure, a p-type metal electrode may be located below the GaAs thin film.

According to an exemplary embodiment of the present disclosure, the sacrificial layer may be AlₓGa₁₋ₓAs.

According to an exemplary embodiment of the present disclosure, the step of attaching a heat resistant structure prevents formation of the electrode layer at the edge of the top surface of the light-absorbing layer.

According to an exemplary embodiment of the present disclosure, the step of forming an electrode layer may include forming an n-type layer, a transparent electrode and a metal grid electrode in turn on the top of the light-absorbing layer.

According to an exemplary embodiment of the present disclosure, the step of attaching a carrier wafer may include attaching the carrier wafer to the top of the electrode layer by using wax in order to protect the light-absorbing layer and the electrode layer.

According to an exemplary embodiment of the present disclosure, the step of separating the GaAs wafer may include removing the sacrificial layer through an epitaxial lift off process to separate the GaAs wafer.

In another aspect, there is provided a method of recycling GaAs substrates, including the steps of: forming an epitaxial CIGS light-absorbing layer on the top of a GaAs wafer; attaching a carrier wafer to the top of the light-absorbing layer; separating the GaAs wafer through an epitaxial lift off process; attaching a metal electrode to the bottom of the light-absorbing layer; bonding copper foil having a metal thin film deposited thereon to the bottom of the metal electrode; separating the carrier wafer; and forming an electrode layer on the top of the light-absorbing layer.

According to an exemplary embodiment of the present disclosure, the step of forming an epitaxial CIGS light-absorbing layer may include the steps of: depositing a sacrificial layer on the top of the GaAs wafer; forming an epitaxial GaAs thin film on the top of the sacrificial layer; and forming an epitaxial CIGS light-absorbing layer on the top of the GaAs thin film.

According to an exemplary embodiment of the present disclosure, a p-type metal electrode may be located below the GaAs thin film.

According to an exemplary embodiment of the present disclosure, the sacrificial layer may be AlₓGa₁₋ₓAs.

According to an exemplary embodiment of the present disclosure, the step of attaching a carrier wafer may include attaching a carrier wafer to the top of the light-absorbing layer by using wax for the purpose of physical supporting in the epitaxial lift off process.

According to an exemplary embodiment of the present disclosure, the metal electrode may have characteristics of an ohmic contact.

According to an exemplary embodiment of the present disclosure, the step of forming an electrode layer may include forming an n-type layer, a transparent electrode and a metal grid electrode in turn on the top of the light-absorbing layer.

According to the exemplary embodiments of the present disclosure, expensive single crystalline GaAs substrates may be recycled in implementing epitaxial single crystalline CIGS solar cells, and thus it is possible to reduce processing costs when commercializing solar cells.

The effects of the present disclosure are not limited to the above-described effects, and should be understood to include all effects deducible from the constitution of the present disclosure described in the detailed description or the claims of the present disclosure.

### BRIEF DESCRIPTION OF THE DRAWINGS

FIG. 1 illustrate a flow of the method of recycling GaAs substrates according to Example 1.

FIG. 2 illustrate a flow of the method of recycling GaAs substrates according to Example 2.

### DETAILED DESCRIPTION

Hereinafter, the present disclosure will be explained with reference to the accompanying drawings. However, the present disclosure may be implemented in various different forms, and thus is not limited to the embodiments described hereinafter. In addition, parts unrelated to the description were omitted in the drawings in order to clearly explain the present disclosure, and similar drawing numerals were used for similar parts throughout the specification.

Throughout the specification, when a part is “linked (connected, contacted, bound)” with another part, it includes not only “directly linked” but also “indirectly linked” with another member interposed therebetween. Also, when a part “includes” a constitutional element, this means that it may further have other constitutional elements, rather than excluding other constitutional elements, unless otherwise stated.

The terms used herein are provided only to describe specific embodiments and are not intended to limit the present disclosure. Singular expressions include plural expressions, unless the context clearly indicates otherwise. In the present specification, terms such as “including” or “having” are intended to specify that there is a feature, number, step, operation, constitutional element, part or a combination thereof described in the specification, and should not be understood as excluding the existence or the possibility of addition of one or more other features, numbers, steps, operations, constitutional elements, parts or combinations thereof.

Hereinafter, exemplary embodiments of the present disclosure will be explained in detail with reference to the accompanying drawings.

Terms used herein are defined as follows.

“CIGS” means Cu (copper), In (indium), Ga (gallium), Se (selenium).

“CIGS solar cell” or “CIGS light-absorbing layer” means a solar cell or light-absorbing layer obtained by using the four types of compounds of Cu (copper), In (indium), Ga (gallium), Se (selenium).

“Wafer” or “substrate” is used as the same meaning.

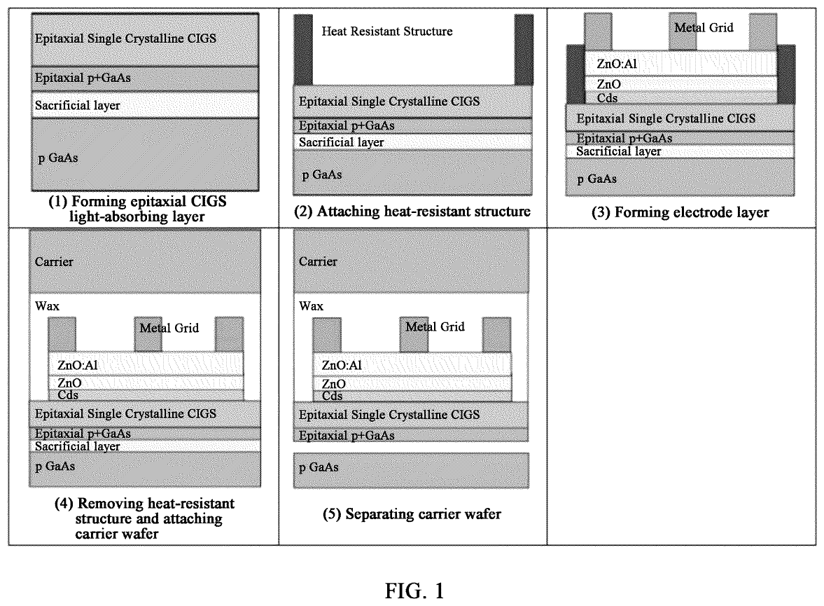

FIG. 1 illustrate a flow of the method of recycling GaAs substrates according to Example 1.

The method of recycling GaAs substrates according to Example 1 of the present disclosure will be explained hereinafter with reference to FIG. 1.

The method of recycling Ga As substrates according to an exemplary embodiment of the present disclosure may include the steps of: forming an epitaxial CIGS (copper indium gallium selenide) light-absorbing layer on the top of a GaAs wafer; attaching a heat resistant structure to the edge of the top surface of the light-absorbing layer; forming an electrode layer on the top of the light-absorbing layer; attaching a carrier wafer to the top of the electrode layer; and separating the GaAs wafer through an epitaxial lift off process.

First, a step of forming an epitaxial CIGS light-absorbing layer on the top of a GaAs wafer is carried out.

The step of forming an epitaxial CIGS light-absorbing layer may include the steps of: depositing a sacrificial layer on the top of the GaAs wafer; forming an epitaxial GaAs thin film on the top of the sacrificial layer; and forming an epitaxial CIGS light-absorbing layer on the top of the GaAs thin film. Herein, the CIGS light-absorbing layer may be implemented as epitaxial single crystals with the epitaxial GaAs layer taken as crystal seeds.

A p-type metal electrode may be located below the GaAs thin film.

The sacrificial layer may be AlₓGa₁₋ₓAs, but is not limited thereto.

Next, a step of attaching a heat resistant structure to the edge of the top surface of the light-absorbing layer is carried out.

The step of attaching a heat resistant structure may be intended to prevent formation of the electrode layer at the edge of the top surface of the light-absorbing layer. Particularly, this step may be intended to prevent formation of an n-type layer and transparent electrode at the edge zone. In this manner, it is possible to prevent a transparent electrode as an oxidized film from being damaged during a process of removing the sacrificial layer below the epitaxial GaAs with an HF-based solution when carrying out an epitaxial lift off process as the subsequent process.

After that, a step of forming an electrode layer on the top of the light-absorbing layer is carried out.

The step of forming an electrode layer may include forming an n-type layer, a transparent electrode and a metal grid electrode in turn on the top of the light-absorbing layer.

After that, a step of attaching a carrier wafer to the top of the electrode layer is carried out.

The step of attaching a carrier wafer may include attaching the carrier wafer to the top of the electrode layer by using wax in order to protect the light-absorbing layer and the electrode layer.

Then, a step of separating the GaAs wafer through an epitaxial lift off process is carried out.

The step of separating the GaAs wafer may include removing the sacrificial layer through an epitaxial lift off process to separate the GaAs wafer.

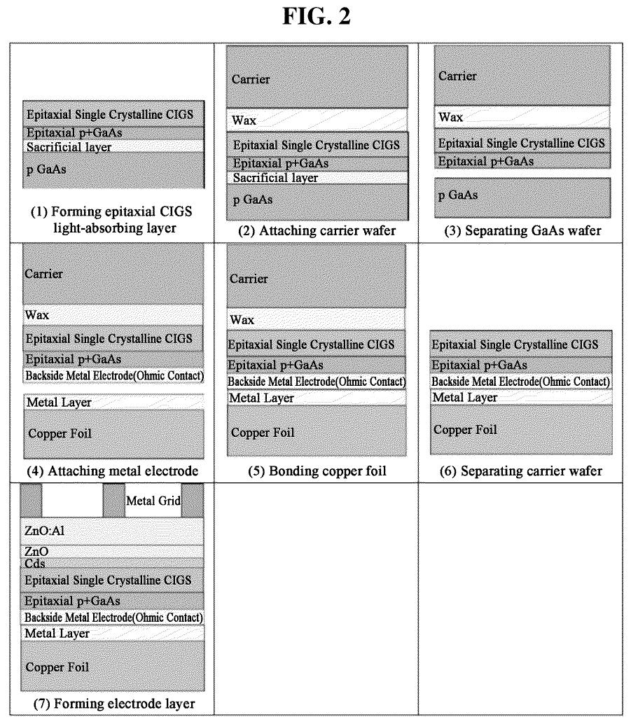

FIG. 2 illustrate a flow of the method of recycling GaAs substrates according to Example 2.

The method of recycling GaAs substrates according to Example 2 of the present disclosure will be explained hereinafter with reference to FIG. 2.

The method of recycling GaAs substrates according to another exemplary embodiment of the present disclosure may include the steps of: forming an epitaxial CIGS light-absorbing layer on the top of a GaAs wafer; attaching a carrier wafer to the top of the light-absorbing layer; separating the GaAs wafer through an epitaxial lift off process; attaching a metal electrode to the bottom of the light-absorbing layer; bonding copper foil having a metal thin film deposited thereon to the bottom of the metal electrode; separating the carrier wafer; and forming an electrode layer on the top of the light-absorbing layer.

First, a step of forming an epitaxial CIGS light-absorbing layer on the top of a GaAs wafer is carried out.

The step of forming an epitaxial CIGS light-absorbing layer may include the steps of: depositing a sacrificial layer on the top of the GaAs wafer; forming an epitaxial GaAs thin film on the top of the sacrificial layer; and forming an epitaxial CIGS light-absorbing layer on the top of the GaAs thin film. Herein, the CIGS light-absorbing layer may be implemented as epitaxial single crystals with the epitaxial GaAs layer taken as crystal seeds.

A p-type metal electrode may be located below the GaAs thin film.

The sacrificial layer may be AlₓGa₁₋ₓAs, but is not limited thereto.

Next, a step of attaching a carrier wafer to the top of the light-absorbing layer is carried out.

The step of attaching a carrier wafer may include attaching a carrier wafer to the top of the light-absorbing layer by using wax for the purpose of physical supporting in the epitaxial lift off process.

After that, a step of separating the GaAs wafer through an epitaxial lift off process is carried out.

A device may be separated from the GaAs wafer by removing the sacrificial layer through the epitaxial lift off process.

After that, a step of attaching a metal electrode to the bottom of the light-absorbing layer is carried out.

A metal thin film having characteristics of an ohmic contact may be deposited on the rear surface of the device including a GaAs thin film so that the metal thin film may be utilized as a rear electrode.

After that, a step of bonding copper foil having a metal thin film deposited thereon to the bottom of the metal electrode is carried out.

The device may be bonded to the copper foil by bonding the metal layer of the device and that of the copper substrate with each other. The reason why the device is bonded to the copper foil is for physically supporting the device.

After that, a step of separating the carrier wafer is carried out.

The device and the carrier wafer may be separated from each other by removing the wax.

Then, a step of forming an electrode layer on the top of the light-absorbing layer is carried out.

The step of forming an electrode layer may include forming an n-type layer, a transparent electrode and a metal grid electrode in turn on the top of the light-absorbing layer.

Hereinafter, the present disclosure will be described in more detail through Examples.

The technology of recycling GaAs substrates according to Example 1 is as follows.

An AlₓGa₁₋ₓAs sacrificial layer is stacked on a high-quality low-resistance P-type GaAs (001) substrate, and an epitaxial GaAs layer is stacked thereon. The sacrificial layer and the epitaxial GaAs layer are stacked by the MOCVD (metal-organic vapor deposition) method. An epitaxial CIGS light-absorbing layer is formed thereon. Herein, the CIGS light-absorbing layer is implemented as epitaxial single crystals with the epitaxial GaAs layer taken as crystal seeds. The CIGS (Cu, In, Ga, Se) light-absorbing layer is formed through co-evaporation. First, a CIGS layer having a CGI (ratio of [Cu]/([Ga]+[In])) of 0.7 is formed to 1.1 μm at a substrate temperature of 550° C. After the CIGS layer is formed, the effusion cell temperature of Ga and In is changed. This is for modifying the CGI by changing the deposition rate of Ga and In. In addition, a CIGS layer having a CGI of 0.4 is formed to 1.1 μm. In both CIGS layers, CGI is maintained at 0.85. Na having a concentration of 2×1018 cm⁻³ is formed through NaF doping. Additionally, KF-PDT (potassium fluoride post-deposition treatment) is carried out at 350° C. Then, a heat resistant structure is attached to the edge of the top surface. This is for preventing formation of an n-type layer and transparent electrode at the edge zone. In this manner, it is possible to prevent a transparent electrode as an oxidized film from being damaged during a process of removing the sacrificial layer below the epitaxial GaAs with an HF-based solution when carrying out an epitaxial lift off process as the subsequent process. In addition, a buffer layer and n-type layer are formed on the top of the CIGS light-absorbing layer. Additionally, a metal grid electrode is formed on the top of the transparent electrode Further, a carrier wafer is attached to the top of the device by using wax. The thin films on the device are not exposed to chemicals by virtue of the wax. Then, the sacrificial layer is removed by using a chemical and an epitaxial lift off process is carried out to separate the device having the CIGS light-absorbing layer from the GaAs wafer. In this manner, the GaAs substrate can be recycled.

The technology of recycling GaAs substrates according to Example 2 is as follows.

An AlₓGa₁₋ₓAs sacrificial layer is stacked on a high-quality low-resistance P-type GaAs (001) substrate, and an epitaxial GaAs layer is stacked thereon. The sacrificial layer and the epitaxial GaAs layer are stacked by the MOCVD method. An epitaxial CIGS light-absorbing layer is formed thereon. Herein, the CIGS light-absorbing layer is implemented as epitaxial single crystals with the epitaxial GaAs layer taken as crystal seeds. The CIGS (Cu, In, Ga, Se) light-absorbing layer is formed through co-evaporation. First, a CIGS layer having a CGI (ratio of [Cu]/([Ga]+[In])) of 0.7 is formed to 1.1 μm at a substrate temperature of 550° C. After the CIGS layer is formed, the effusion cell temperature of Ga and In is changed. This is for modifying the CGI by changing the deposition rate of Ga and In. In addition, a CIGS layer having a CGI of 0.4 is formed to 1.1 μm. In both CIGS layers, CGI is maintained at 0.85. Na having a concentration of 2×10¹⁸ cm⁻³ is formed through NaF doping. Additionally, KF-PDT is carried out at 350° C. Then, a device is attached to a carrier wafer by using wax. This is for physical supporting during an epitaxial lift off process. The device is separated from the GaAs wafer by removing the sacrificial layer through an epitaxial lift off process. A metal thin film having characteristics of an ohmic contact is deposited on the rear surface of the device including a GaAs thin film so that the metal thin film may be utilized as a rear electrode. Then, the device is bonded to thick copper foil having a metal thin film deposited thereon. The metal layer of the device and that of the copper substrate are bonded with each other so that the device may be bonded to the copper foil. The reason why the device is bonded to the copper foil is for physically supporting the device. Then, the wax is removed to separate the device from the carrier wafer, and an n-type layer, transparent electrode and a metal grid electrode are formed, in turn, on the top of the device to finish the device. In this manner, the GaAs substrate can be recycled.

The foregoing description of the present disclosure is for illustrative purposes only, and those skilled in the art will understand that it may be easily transformed into other specific forms without changing the technical idea or essential features of the present disclosure. Therefore, it should be understood that the embodiments described above are exemplary and not limited in all aspects. For example, each constitutional element described in a single form may be implemented separately, or similarly, constitutional elements described as separated may be implemented in a combined form.

The scope of the present disclosure should be defined by the claims described hereinafter, and all changes or modifications derived from the meaning and scope of the claims and the equivalent concept thereof should be interpreted as being included in the scope of the present invention.

What is claimed is:

1. A method of recycling GaAs substrates, comprising the steps of:
forming an epitaxial CIGS (copper indium gallium selenide) light-absorbing layer on the top of a GaAs wafer;
attaching a heat resistant structure to the edge of the top surface of the light-absorbing layer;
forming an electrode layer on the top of the light-absorbing layer;
attaching a carrier wafer to the top of the electrode layer; and
separating the GaAs wafer through an epitaxial lift off process.

2. The method of recycling GaAs substrates according to claim 1, wherein the step of forming an epitaxial CIGS light-absorbing layer comprises the steps of:
depositing a sacrificial layer on the top of the GaAs wafer;
forming an epitaxial GaAs thin film on the top of the sacrificial layer; and
forming an epitaxial CIGS light-absorbing layer on the top of the GaAs thin film.

3. The method of recycling GaAs substrates according to claim 2, wherein a p-type metal electrode is located below the GaAs thin film.

4. The method of recycling GaAs substrates according to claim 2, wherein the sacrificial layer is AlₓGa₁₋ₓAs.

5. The method of recycling GaAs substrates according to claim 1, wherein the step of attaching a heat resistant structure prevents formation of the electrode layer at the edge of the top surface of the light-absorbing layer.

6. The method of recycling GaAs substrates according to claim 1, wherein the step of forming an electrode layer comprises forming an n-type layer, a transparent electrode and a metal grid electrode in turn on the top of the light-absorbing layer.

7. The method of recycling GaAs substrates according to claim 1, wherein the step of attaching a carrier wafer comprises attaching the carrier wafer to the top of the electrode layer by using wax in order to protect the light-absorbing layer and the electrode layer.

8. The method of recycling GaAs substrates according to claim 1, wherein the step of separating the GaAs wafer comprises removing the sacrificial layer through an epitaxial lift off process to separate the GaAs wafer.

9. A method of recycling GaAs substrates, comprising the steps of:
forming an epitaxial CIGS light-absorbing layer on the top of a GaAs wafer;
attaching a carrier wafer to the top of the light-absorbing layer;
separating the GaAs wafer through an epitaxial lift off process;
attaching a metal electrode to the bottom of the light-absorbing layer;
bonding copper foil having a metal thin film deposited thereon to the bottom of the metal electrode;
separating the carrier wafer; and
forming an electrode layer on the top of the light-absorbing layer.

10. The method of recycling GaAs substrates according to claim 9, wherein the step of forming an epitaxial CIGS light-absorbing layer comprises the steps of:
depositing a sacrificial layer on the top of the GaAs wafer;
forming an epitaxial GaAs thin film on the top of the sacrificial layer; and
forming an epitaxial CIGS light-absorbing layer on the top of the GaAs thin film.

11. The method of recycling GaAs substrates according to claim 10, wherein a p-type metal electrode is located below the GaAs thin film.

12. The method of recycling GaAs substrates according to claim 10, wherein the sacrificial layer is AlₓGa₁₋ₓAs.

13. The method of recycling GaAs substrates according to claim 9, wherein the step of attaching a carrier wafer comprises attaching a carrier wafer to the top of the light-absorbing layer by using wax for the purpose of physical supporting in the epitaxial lift off process.

14. The method of recycling GaAs substrates according to claim 9, wherein the metal electrode has characteristics of an ohmic contact.

15. The method of recycling GaAs substrates according to claim 9, wherein the step of forming an electrode layer comprises forming an n-type layer, a transparent electrode and a metal grid electrode in turn on the top of the light-absorbing layer.
